(19) United States
(12) Patent Application Publication
(10) Pub. No.: US 2007/0069811 A1
(43) Pub. Date: Mar. 29, 2007

(54) Line drivers with extended linearity

(76) Inventors: James T. Schley-May, Nevada City, CA (US); R. Barry Angell, Nevada City, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/232,514

(22) Filed: Sep. 21, 2005

(51) Int. Cl. H03F 1/36

(52) U.S. Cl. 330/75

(57) ABSTRACT

Line drivers with extended linearity are described herein. In one embodiment, an example of a line driver includes, but is not limited to, a first amplifier having a first input, a second amplifier having a second input, the first and second amplifiers driving a load of a communication line, and a trans-conductance stage device coupled to the first and second amplifiers. The trans-conductance stage device is configured to sense a first error voltage across the first input of the first amplifier and to provide a first feedback to the second input of the second amplifier. The trans-conductance stage device is configured to sense a second error voltage across the second input of the second amplifier and to provide a second feedback to the first input of the first amplifier. Other methods and apparatuses are also described.

### FIELD OF THE INVENTION

The present invention relates generally to communication devices. More particularly, this invention relates to line drivers with extended linearity.

### BACKGROUND

A communication device, such as an xDSL (x digital subscriber line), typically includes a line driver to drive a load onto a communication line (e.g., a phone line). Because this line driver, for cost reasons, may be integrated into the analog front end (AFE) chip which contains other functions, such as, for example, an analog to digital converter (ADC) and/or a digital to analog converter (DAC), realizing a high performance differential line driver is difficult to achieve. This driver is required to produce high current levels, swing output voltages close to the rails, and have low distortion and a high gain bandwidth product. Conventional xDSL AFE chip designers have not been successful in implementing an integrated differential line driver that does not compromise system performance one way or another.

FIG. 1 is a schematic diagram illustrating a conventional line driver circuit. In addition to a first differential amplifier LD1, referring to FIG. 1, the line driver includes a second differential amplifier LD2 with another set of output resistors Rt so that the outputs of two amplifiers sum together to drive the load, which in a xDSL systems is the phone line connected through a transformer. In addition, the line driver includes a differential trans-conductance stage (also referred to as a gm stage) with gain in the range of 1/(R1∥R2). This gm stage monitors the error voltage present across the differential inputs of LD1. If the amplifier were perfectly ideal, there would be no error voltage. But to the extent that LD1 is imperfect and limited in gain bandwidth and linearity, an error voltage will be present.

The gm stage generates a current proportional to the error voltage and injects it into the differential inputs of LD2. This correction current will induce Vout2 to compensate for the deficiencies in Vout1 by moving in the opposite direction. Together, Vout1 and Vout2 will sum to produce an average which will be closer to the desired signal.

One significant problem with this approach is the need for another set of output pins for the second amplifier. A second limitation is the need for external resistors to sum the two outputs together. In some devices, such as an xDSL device, output resistors are either not present if the load is driven directly, or they are not accessible to the AFE chip pins.

### SUMMARY OF THE DESCRIPTION

Line drivers with extended linearity are described herein. In one embodiment, an example of a line driver includes, but is not limited to, a first amplifier having a first input, a second amplifier having a second input, the first and second amplifiers driving a load of a communication line, and a trans-conductance stage device coupled to the first and second amplifiers. The trans-conductance stage device is configured to sense a first error voltage across the first input of the first amplifier and to provide a first feedback to the second input of the second amplifier. The trans-conductance stage device is configured to sense a second error voltage across the second input of the second amplifier and to provide a second feedback to the first input of the first amplifier.

Other features of the present invention will be apparent from the accompanying drawings and from the detailed description which follows.

### BRIEF DESCRIPTION OF THE DRAWINGS

The present invention is illustrated by way of example and not limitation in the figures of the accompanying drawings in which like references indicate similar elements.

FIG. 1 is a conventional line driver circuit.

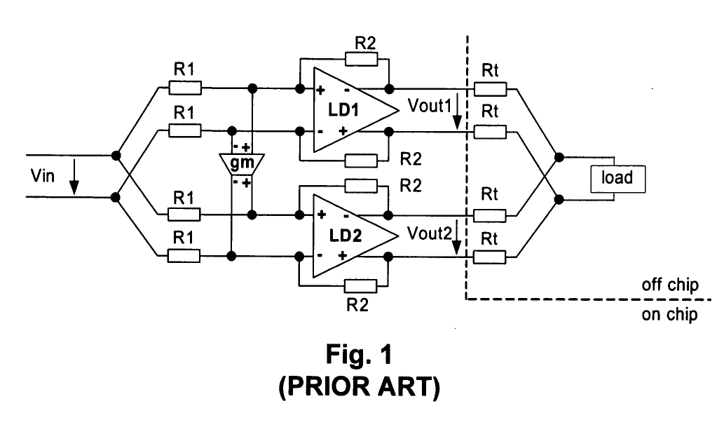

FIG. 2 illustrates a block diagram of a communication system which may be used with an embodiment of the invention

FIG. 3 is a diagram of a communication device in accordance with one embodiment of the invention.

FIG. 4 is a schematic diagram illustrating an embodiment of a line driver circuit.

FIG. 5 is a schematic diagram illustrating another embodiment of a line driver circuit.

FIG. 6 is a schematic diagram illustrating another embodiment of a line driver circuit.

### DETAILED DESCRIPTION

Line drivers with extended linearity are described herein. In the following description, numerous details are set forth to provide a more thorough explanation of embodiments of the present invention. It will be apparent, however, to one skilled in the art, that embodiments of the present invention may be practiced without these specific details. In other instances, well-known structures and devices are shown in block diagram form, rather than in detail, in order to avoid obscuring embodiments of the present invention.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification do not necessarily all refer to the same embodiment.

Throughout this application, a DSL modem is used as an example of a communication device to illustrate embodiments of the disclosure. It will be appreciated that other communication devices, such as network interface card (NIC) or cable modem, etc., may be applied.

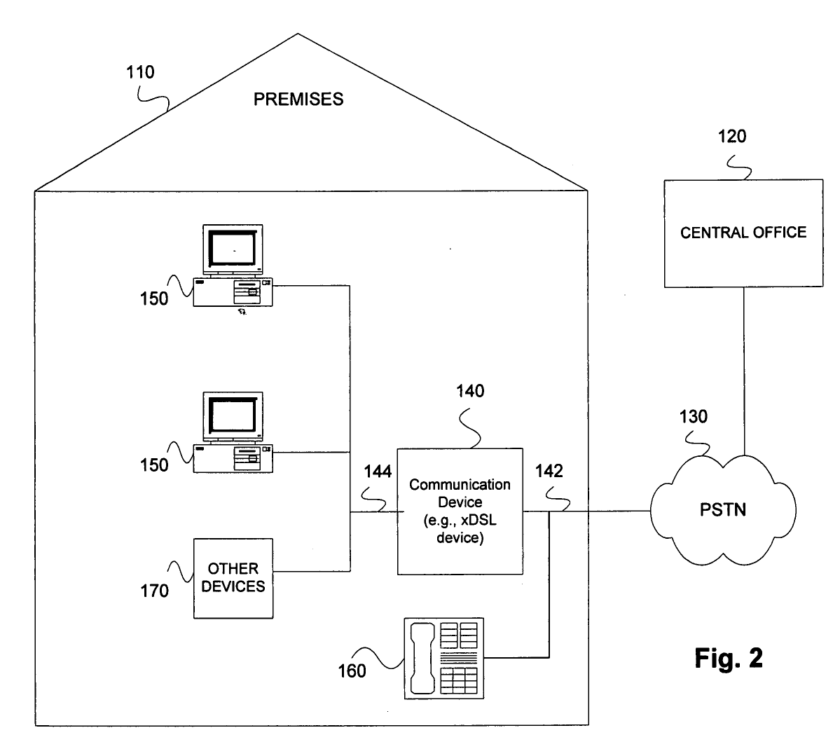

FIG. 2 is a block diagram of an embodiment of a communication system having a communication device that includes a line driver circuit. According to one embodiment, a system example includes a premises 110, having property with any type of structure, may couple via a line 142 to a Public Switched Telephone Network (PSTN) 130. PSTN 130 may provide copper wires as a telecommunications medium and can also include Cat 5 copper cables (not shown) and fiber optic cables (not shown). PSTN 130 may further couple to a central office 120, which provides telecommunications services for a particular area. Central office 120, operated by a service provider (not shown), provides switching technologies for Plain Old Telephone Service (POTS), Integrated Services Digital Network (ISDN) service, and/or xDSL service, etc.

In premises 110, a communication device 140, such as a DSL compatible modem or router, communicates via line 142 with PSTN 130 and via a path 144 with multiple other telecommunication devices. The telecommunication devices may include, but are not limited to, computer(s) 150 with network/telecommunication hardware and/or software (not shown) and other devices 170, such as set-top boxes, home network gateways, PDAs (Personal Digital Assistants), and printers. A telephone 160 may couple to line 142 and includes a filter, such as a low pass filter (not shown), for filtering out non-POTS band signals. Other POTS devices, such as a facsimile machine, may also couple to line 142.

Communication device 140, which may be an xDSL modem, includes a line interface or driver circuit that is able to transmit and/or receive signals to/from line 142 coupled to PSTN 130. In one embodiment, the line driver circuit may be implemented using one or more techniques which will be described in details further below.

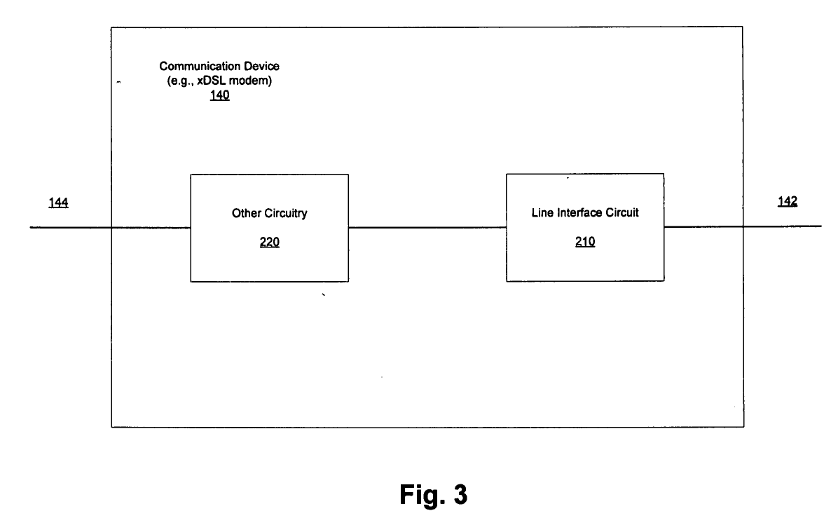

FIG. 3 is a schematic diagram of a communication device according to one embodiment of the invention. For example, communication device 140 may be an xDSL device used as communication device 140 of FIG. 2. In one embodiment, xDSL device 140 includes, but is not limited to, a line interface circuit 210, which may include a line driver circuit described through this application, and other xDSL circuitry 220. Line interface circuit 210 may be, for example, a 2-to-4 wire converter that electromagnetically couples xDSL device 140 to line 142. Other xDSL circuitry 220, which includes filters and a transceiver, communicates via path 144 with computers 150 and other device 170. Other components may also be included.

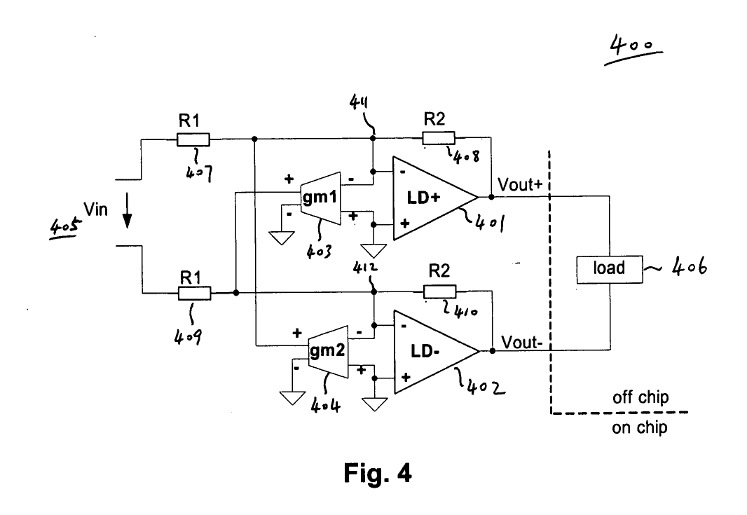

FIG. 4 is a schematic diagram illustrating an embodiment of a line driver circuit of a communication device. For example, line driver 400 may be implemented as a part of communication device 140 of FIGS. 2 and 3, particularly, as a part of line interface circuit 210 of FIG. 3. In one embodiment, as shown in FIG. 4, amplifiers LD+ and LD− may be differential input, single-output line drivers. Trans-conductance stage devices gm1 and gm2 may be cross wired between LD+ and LD−. Each trans-conductance stage senses its driver's input error voltage and generates a corresponding correction current which is injected into the other driver, out of phase. This induces the other driver's output to essentially correct by moving in the opposite direction. In a particular embodiment, gains of approximately 2/R1 for each gm stage work well when R2=R1. By the addition of the second gm stage, the ability to correct for non-linearity is greatly improved, as is the gain bandwidth product of the whole system.

In one embodiment, line driver 400 includes, but is not limited to, a first amplifier having a first input and a second amplifier having a second input, where the first and second amplifiers are used to drive a load of a communication line, such as, for example, a telephone line. The line driver 400 further includes a trans-conductance stage device (e.g., a gm stage device) coupled to the first and second amplifiers. The trans-conductance stage device is configured to sense a first error voltage across the first input of the first amplifier and to provide a first feedback to the second input of the second amplifier. The trans-conductance stage device is also configured to sense a second error voltage across the second input of the second amplifier and to provide a second feedback to the first input of the first amplifier.

In one embodiment, referring to FIG. 4, the line driver circuit 400 includes a first amplifier LD+ 401 and a second amplifier LD− 402. In this embodiment, the first and second amplifiers 401-402 each may include differential inputs (e.g., first and second inputs), such as a positive input (also referred to as a normal or regular input) and a negative input (also referred to as an inverted input) and an output, which may be a single ended or a differential output. In addition, the line driver circuit 400 further includes a first trans-conductance stage device 403 (e.g., gm1) and a second trans-conductance stage device 404 (e.g., gm2).

The trans-conductance stage device 403 includes an input coupled to the inputs of the amplifier 401 to sense an error voltage across the inputs of amplifier 401. In response to the error voltage sensed across the inputs of the amplifier 401, trans-conductance stage device 403 provides a feedback to one or more inputs of amplifier 402 to enable amplifier 402 to compensate an output of amplifier 401 as a result of the error voltage.

Similarly, the trans-conductance stage device 404 includes an input coupled to the inputs of the amplifier 402 to sense an error voltage across the inputs of amplifier 402. In response to the error voltage sensed across the inputs of the amplifier 402, trans-conductance stage device 404 provides a feedback to one or more inputs of amplifier 401 to enable amplifier 401 to compensate an output of amplifier 402 as a result of the error voltage.

Specifically, for example, in response to an error voltage across inputs of amplifier 401, the trans-conductance stage device 403 generates a current proportional to the error voltage and injects it into the differential inputs of amplifier 402. This correction current will induce an output of amplifier 402 to compensate for the deficiencies in an output of amplifier 401 by moving in the opposite direction. Together, outputs of the amplifiers 401-402 produce an average which will be closer to the desired signal.

Another way of looking at this is that more loop gain is being introduced into the system, with a resultant increase in linearity and bandwidth. It should be noted that the trans-conductance stage device may have a gain bandwidth product that is higher than the line drivers. In addition, the trans-conductance stage device may have large voltage compliance on its inputs and outputs, since the error voltages will get larger than standard amplifier designs without this technique.

Referring back to FIG. 4, trans-conductance stage device 403 includes differential inputs (e.g., negative and positive inputs), where the negative input is coupled to a negative input of amplifier 401 forming node 411 and the positive input is coupled to a positive input of amplifier 401. The trans-conductance stage device 403 further includes differential outputs (e.g., positive and negative outputs), where the positive output is coupled to a negative input of amplifier 402 forming node 412. Further, the negative output and positive input of the trans-conductance stage device 403, as well as the positive input of amplifier 401 may be coupled to a predetermined potential, such as, for example, a ground potential.

Similarly, according to one embodiment, trans-conductance stage device 404 includes differential inputs (e.g., negative and positive inputs), where the negative input is coupled to a negative input of amplifier 402 forming node 412 and the positive input is coupled to a positive input of amplifier 402. The trans-conductance stage device 404 further includes differential outputs (e.g., a positive and negative outputs), where the positive output is coupled to a negative input of amplifier 401 forming node 411. Further, the negative output and positive input of the trans-conductance stage device 404, as well as the positive input of amplifier 402 may be coupled to a predetermined potential, such as, for example, a ground potential.

Further, one or more parameters, such as gains, of amplifier 401 and/or trans-conductance stage device 403 may be determined by resistors 407 and 408. Similarly, one or more parameters, such as gains, of amplifier 402 and/or trans-conductance stage device 404 may be determined by resistors 409 and 410. Together, the line driver circuit 400 drives a load 406 of a communication line (e.g., a phone line) in response to input signals received from input 405. Other components may also be included.

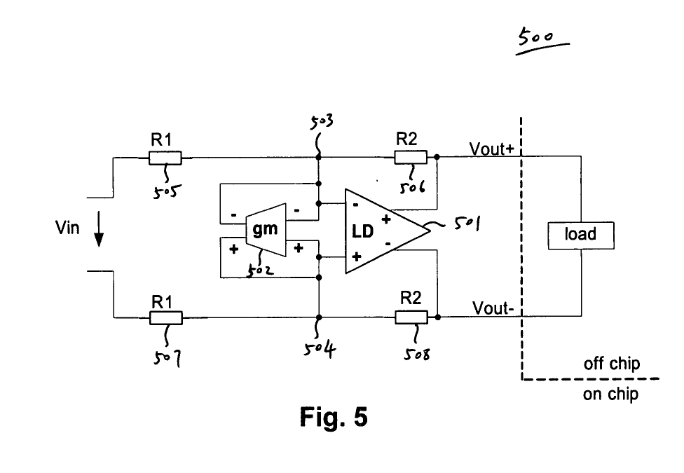

FIG. 5 is a schematic diagram illustrating another embodiment of a line driver circuit for a communication device. For example, line driver 500 may be implemented as a part of communication device 140 of FIGS. 2 and 3, particularly, as a part of line interface circuit 210 of FIG. 3. In this embodiment, it is a simplification and reduction of the schematic in FIG. 4. The gm stage senses error voltage across differential line driver LD and applies positive current back into the inputs. This current forces the outputs to move closer to the desired levels. In a particular embodiment, a gm stage gain of approximately 2/R1 works well when R2=R1.

In one embodiment, line driver circuit 500 includes, but is not limited to, an amplifier, including a first input and a second input, to drive a load of a communication line (e.g., a phone line) and a trans-conductance stage device (e.g., a gm stage device) coupled to the amplifier to sense an error voltage across the first and second inputs of the amplifier. The trans-conductance stage device is configured to provide a first feedback to the first input and a second feedback to the second input, in response to the sensed error voltage across the first and second inputs of the amplifier.

Referring to FIG. 5, line driver 500 includes an amplifier 501 having differential inputs, such as a negative or inverted input and a positive or normal input, coupled to a trans-conductance stage device 502. In one embodiment, the trans-conductance stage device 502 includes differential inputs and differential outputs. The differential inputs of the trans-conductance stage device 502 are coupled to inputs of the amplifier 501 to sense an error voltage across the inputs of the amplifier 501. In addition, according to one embodiment, the trans-conductance stage device 502 includes differential outputs each coupled to one of the differential inputs of the amplifier 501 to provide one or more feedback to one or more inputs of the amplifier 501, in response to the sensed error voltage across the inputs of the amplifier 501.

Specifically, referred to FIG. 5, according to one embodiment, an inverted input of amplifier 501 is coupled to an inverted input of the trans-conductance stage device 502, forming a node 503. In addition, an inverted output of the trans-conductance stage device 502 is also coupled to node 503 to provide a negative feedback to the inverted input of the amplifier 501. Further, a positive output of amplifier 501 is also coupled to node 503 via resistor 506.

Similarly, according to one embodiment, a positive input of amplifier 501 is coupled to a positive input of the trans-conductance stage device 502, forming a node 504. In addition, a positive output of the trans-conductance stage device 502 is also coupled to node 504 to provide a positive feedback to the positive input of the amplifier 501. Further, an inverted output of amplifier 501 is also coupled to node 504 via resistor 508. One or more parameters of amplifier 501 and/or the trans-conductance stage device 502 may be determined based on some or all of the resistors 505-508. Other components may also be included.

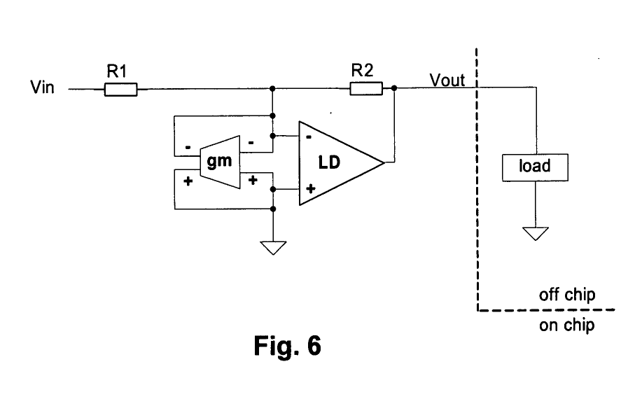

FIG. 6 is a schematic diagram illustrating another embodiment of a line driver circuit. For example, line driver 500 may be implemented as a part of communication device 140 of FIGS. 2 and 3, particularly, as a part of line interface circuit 210 of FIG. 3. This embodiment is a further simplification and reduction of the circuit of FIG. 5. This figure shows that the technique can be applied to a differential input amplifier with a single-ended output, and is not dependent on the differential outputs at all.

Thus, line drivers with extended linearity have been described herein. In the foregoing specification, embodiments of the invention have been described with reference to specific exemplary embodiments thereof. It will be evident that various modifications may be made thereto without departing from the broader spirit and scope of the invention as set forth in the following claims. The specification and drawings are, accordingly, to be regarded in an illustrative sense rather than a restrictive sense.

What is claimed is:

1. A line driver of a communication device, comprising:
a first amplifier having a first input;
a second amplifier having a second input, the first and second amplifiers driving a load of a communication line; and
a trans-conductance stage device coupled to the first and second amplifiers, wherein the trans-conductance stage device is configured to sense a first error voltage across the first input of the first amplifier and to provide a first feedback to the second input of the second amplifier, and wherein the trans-conductance stage device is configured to sense a second error voltage across the second input of the second amplifier and to provide a second feedback to the first input of the first amplifier.

2. The line driver of claim 1, wherein the trans-conductance stage device comprises a first trans-conductance stage device and a second trans-conductance stage device to sense the first and second error voltages of the first and second amplifiers respectively.

3. The line driver of claim 2, wherein in response to a first error voltage of the first amplifier, the first trans-conductance stage device is configured to generate a first current proportion to the first error voltage to injected into the second input of the second amplifier, such that the second amplifier compensates the first amplifier as a result of the first error voltage.

4. The line driver of claim 3, wherein in response to a second error voltage of the second amplifier, the second trans-conductance stage device is configured to generate a second current proportion to the second error voltage to injected into the first input of the first amplifier, such that the first amplifier compensates the second amplifier as a result of the second error voltage.

5. The line driver of claim 4, wherein at least one output of the first and second amplifiers shifts in an opposite direction with respect to each other in response to at least one of the first and second error voltages.

6. The line driver of claim 2, wherein each of the first and second amplifiers includes a single-ended output and differential inputs, and wherein each of the first and second trans-conductance stage devices includes differential inputs and outputs.

7. The line driver of claim 6, wherein an inverted input of the first trans-conductance stage device is coupled to an inverted input of the first amplifier, and wherein an output of the first trans-conductance stage device is coupled to an inverted input of the second amplifier.

8. The line driver of claim 7, wherein an inverted output of the first trans-conductance stage device is coupled to a regular input of the first amplifier.

9. The line driver of claim 7, wherein an inverted input of the second trans-conductance stage device is coupled to an inverted input of the second amplifier, and wherein an output of the second trans-conductance stage device is coupled to an inverted input of the first amplifier.

10. The line driver of claim 9, wherein an inverted output of the second trans-conductance stage device is coupled to a regular input of the second amplifier.

11. The line driver of claim 1, wherein the first and second amplifiers are configured to drive the load of the communication line without a summing resistor to sum outputs of the first and second amplifiers.

12. The line driver of claim 1, wherein the communication device is a DSL (digital subscriber line) compatible modem.

13. A communication device, comprising:
an analog front end (AFE) chip having a line driver to drive a load of a communication line, the line driver including
a first amplifier having a first input,
a second amplifier having a second input, the first and second amplifiers driving a load of a communication line, and
a trans-conductance stage device coupled to the first and second amplifiers, wherein the trans-conductance stage device is configured to sense a first error voltage across the first input of the first amplifier and to provide a first feedback to the second input of the second amplifier, and wherein the trans-conductance stage device is configured to sense a second error voltage across the second input of the second amplifier and to provide a second feedback to the first input of the first amplifier.

14. A line driver of a communication device, comprising:
an amplifier to drive a load of a communication line, the amplifier having a first input and a second input; and
a trans-conductance stage device coupled to the amplifier to sense an error voltage across the first and second inputs, wherein the trans-conductance stage device is configured to provide a first feedback to the first input and to provide a second feedback to the second input in response to the error voltage across the first and second inputs.

15. The line driver of claim 14, wherein the trans-conductance stage device comprises a first output coupled to the first input of the amplifier, and wherein the trans-conductance stage device comprises a second output coupled to the second input of the amplifier.

16. The line driver of claim 15, wherein the trans-conductance stage device further comprises a first input coupled to the first input of the amplifier, and wherein the trans-conductance stage device further comprises a second input coupled to the second input of the amplifier.

17. The line driver of claim 16, wherein the first input of the amplifier is a regular input and a second input of the amplifier is an inverted input.

18. The line driver of claim 17, wherein the first input of the trans-conductance stage device is a regular input and the second input of the trans-conductance stage device is an inverted input, and wherein the first output of the trans-conductance stage device is a regular output and the second output of the trans-conductance stage device is an inverted output.

19. The line driver of claim 16, wherein the amplifier is a single-ended output amplifier.

20. The line driver of claim 16, wherein the amplifier comprises a first output coupled to a second input of the amplifier via a first resistor, and wherein the amplifier further comprises a second output coupled to a first input of the amplifier via a second resistor.

21. The line driver of claim 14, wherein the communication device is a DSL (digital subscriber line) compatible modem.

22. A communication device, comprising:
an analog front end (AFE) chip having a line driver to drive a load of a communication line, the line driver including
an amplifier to drive a load of a communication line, the amplifier having a first input and a second input, and
a trans-conductance stage device coupled to the amplifier to sense an error voltage across the first and second inputs, wherein the trans-conductance stage device is configured to provide a first feedback to the first input and to provide a second feedback to the second input in response to the error voltage across the first and second inputs.
